(19) United States
(12) Patent Application Publication
(10) Pub. No.: US 2004/0187905 A1
(43) Pub. Date: Sep. 30, 2004

(54) Thermoelectric materials with enhanced seebeck coefficient

(76) Inventors: Joseph Pierre Heremans, Troy, MI (US); Christopher M. Thrush, Shelby Township, MI (US); Donald T. Morelli, White Lake, MI (US)

Correspondence Address: RADER, FISHMAN & GRAUER PLLC, 39533 WOODWARD AVENUE, SUITE 140, BLOOMFIELD HILLS, MI, 48304-0610, US

(21) Appl. No.: 10/808,180

(22) Filed: Mar. 24, 2004

Related U.S. Application Data
(60) Provisional application No. 60/458,129, filed on Mar. 27, 2003.

(51) Int. Cl. H01L 35/22; H01L 35/16; H01L 35/12

(52) U.S. Cl. 136/238; 136/236.1

(57) ABSTRACT

A thermoelectric nanogranular material with an enhanced Seebeck coefficient is provided. The thermoelectric nanogranular material includes particles having a grain size d. The grain size d is characterized by the relationship mfp/2<d<5mfp, where mfp is the phonon-limited mean free path of an equivalent bulk thermoelectric material prior to processing the bulk thermoelectric material into the thermoelectric nanogranular material having a grain size d. A method of making a thermoelectric nanogranular material is also provided. The method includes preparing a bulk thermoelectric material, reducing the bulk thermoelectric material into a powder, and filtering the powder to retain only those particles having a grain size d. The method also includes pressing the retained particles at a predetermined pressure and sintering the pressed particles at a predetermined temperature for a predetermined period of time in a predetermined atmosphere.

### CROSS-REFERENCE TO RELATED APPLICATIONS

This application claims priority to U.S. provisional patent application 60/458,129 filed on Mar. 27, 2003, which is incorporated herein by reference in its entirety.

### BACKGROUND OF THE INVENTION

1. Field of the Invention

This invention relates generally to thermoelectric materials and, more particularly, to thermoelectric materials with an enhanced Seebeck coefficient and a method for manufacturing same.

2. Description of the Related Art

As is known in the art, there exists a class of materials referred to as thermoelectric materials. A thermoelectric material is a type of material that can directly convert thermal energy into electrical energy or vice versa. Among other benefits, thermoelectric materials offer the potential for realizing solid-state cooling without the use of vapor compression refrigeration or air-conditioning technology. Particularly, thermoelectric materials provide a desirable alternative to using compressed gases such as Freon, which is banned, R134a, which is on a list of greenhouse gases that may be banned, or CO2, which requires a high-pressure vapor-compression cycle that is inefficient at certain temperatures. However, traditional thermoelectric materials are less efficient than common R134a-based vapor-compression systems. Thermoelectric materials can also generate electrical power from heat.

The efficiency of a thermoelectric material is characterized by the “Thermoelectric Figure of Merit”, which is defined as the square of its Seebeck coefficient times its electrical conductivity divided by its thermal conductivity. The Seebeck coefficient is a measure of the “thermoelectric pumping power”, i.e. the amount of heat that a material can pump per unit of electrical current. The electrical conductivity is a measure of electrical losses in a material, and the thermal conductivity is a measure of heat that is lost as it flows back against the heat pumped by a material.

A relatively high-efficiency thermoelectric material has been proposed that includes PbSeTe/PbTe quantum dot superlattice (QDSL) structures. The proposed QDSL structures exhibit an enhanced Seebeck coefficient and thermoelectric power factor. The combination of a relatively larger power factor with low lattice thermal conductivity provides a significant increase in the thermoelectric figure of merit for these QDSL structures compared to their bulk alloys. The proposed QDSL structures are prepared using molecular beam epitaxy or MBE. While multilayer structures prepared by molecular beam epitaxy provide materials having improved thermoelectric properties, molecular beam epitaxy is not amenable to production of these materials cost effectively on a large scale. Accordingly, there exists a need for an improved method of manufacturing thermoelectric materials having an enhanced Seebeck coefficient on a relatively large scale.

### SUMMARY OF THE INVENTION

A thermoelectric nanogranular material with an enhanced Seebeck coefficient is provided. The thermoelectric nanogranular material includes particles having a grain size d. The grain size d is characterized by the relationship mfp/2<d<5mfp, where mfp is the phonon-limited mean free path of an equivalent bulk thermoelectric material prior to processing the bulk thermoelectric material into the thermoelectric nanogranular material having a grain size d.

A method of making a thermoelectric nanogranular material is also provided. The method includes preparing a bulk thermoelectric material, reducing the bulk thermoelectric material into a powder, and filtering the powder to retain only those particles having a grain size d. The method also includes pressing the retained particles at a predetermined pressure and sintering the pressed particles at a predetermined temperature for a predetermined period of time in a predetermined atmosphere.

### BRIEF DESCRIPTION OF THE DRAWINGS

Embodiments of the invention will now be described, by way of example, with reference to the accompanying drawings, wherein:

FIG. 1 is a flow chart of a method of making a thermoelectric nanogranular material according to an embodiment of the invention;

FIG. 2 is a plot of the Seebeck coefficient for various PbTe thermoelectric material samples as a function of electron or hole density;

FIG. 3 is a plot of phonon-limited mean free path versus temperature for bulk PbTe in accordance with an embodiment of the invention; and

FIG. 4 is a plot of an experimentally measured X-ray diffraction (XRD) spectrum for a PbTe nanogranular thermoelectric material according to an embodiment of the invention.

### DETAILED DESCRIPTION OF THE INVENTION

The present invention includes thermoelectric nanogranular materials, such as PbTe-based materials, having an enhanced Seebeck coefficient, and a method of manufacturing thermoelectric nanogranular materials to obtain an enhancement of the Seebeck coefficient. Among other benefits, the method of making thermoelectric nanogranular materials of the present invention is more amenable to cost effective, large scale production of thermoelectric nanogranular materials than traditional methods of producing thermoelectric materials, such as molecular beam epitaxy (MBE). While the method of the present invention will be described below for PbTe-based materials that exhibit an enhanced Seebeck coefficient similar to that in proposed QDSL structures, the disclosed method is not intended to be limited thereto. Indeed, the disclosed method of manufacturing enhanced Seebeck coefficient thermoelectric nanogranular materials is suitable for use in preparing other thermoelectric materials, such as PbSe, PbS, SnTe, and SnSe compounds and their solid solutions. Moreover, the disclosed method is suitable for use in preparing other enhanced Seebeck coefficient thermoelectric nanogranular materials, such as Bi₂Te₃, Bi₂Se₃, Sb₂Te₃ and Sb₃Se₃ compounds and their solid solutions, or BiSb alloys. For reference, PbTe-based materials include all lead and tin chalcogenides and their alloys, Bi₂Te₃ includes all (Bi₁₋ₓSbₓ)₂(Te_{1-y}Se_{y})₃ alloys and Bi includes all Bi₁₋ₓSbₓ alloys.

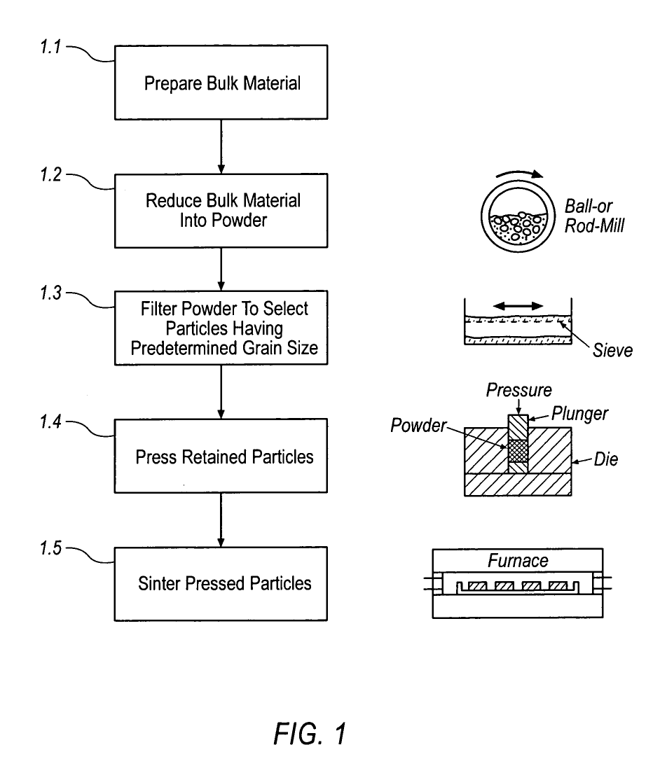

Referring to FIG. 1, a method for making enhanced Seebeck coefficient thermoelectric materials will be described according to an embodiment of the invention. In the illustrated embodiment, PbTe alloy compounds are prepared (step 1.1), for example, by melting elemental Pb pellets and Te chips or previously compounded PbTe chips (e.g., PbTe chips manufactured by Alfa Corporation) at approximately 1000° C. overnight under a pressure of less than about 1.0E-5 Torr inside of a quartz ampoule, followed by quenching the ampoule in cold water. During this part of the process, excess amounts of Pb or Te may be added, or another impurity, such as Bi, T1, Bi₂Te₃, B1₂ or the like may be added, the purpose of which is to endow the resulting ingot with the desired electron (or hole) density. This part of the process is well known to those skilled in the art of semiconductor compound preparation (See, e.g., Ravich et al., “Semiconducting lead chalcogenides”, Plenum Press, New York, 1970).

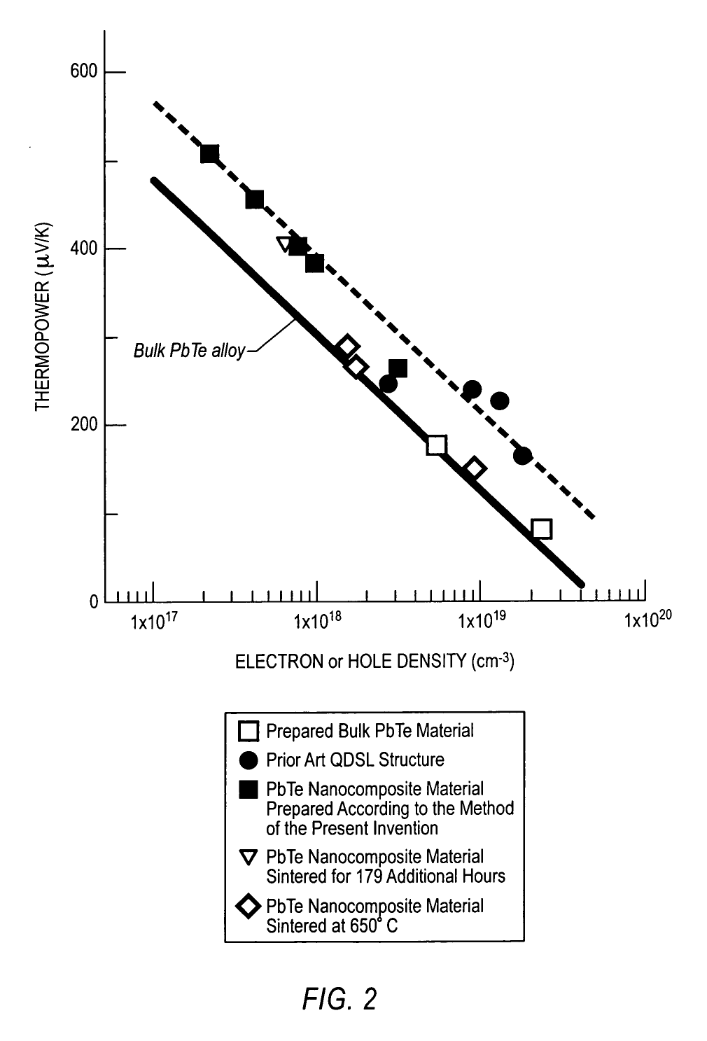

For bulk PbTe ingots made by this or similar methods, there is a well defined relationship between the Seebeck coefficient and the electron (or hole) density. A representation of the relationship between the Seebeck coefficient and the electron (or hole) density for a bulk PbTe alloy is shown in FIG. 2. To verify that the PbTe ingots made by the above described process behave similarly, the Seebeck coefficient of several PbTe ingots may be measured using an industry standard four probe technique. The measured results are also shown in FIG. 2 and agree with the expected behavior.

Referring again to the embodiment illustrated in FIG. 1, the PbTe ingots are ground into a coarse powder using a mortar and pestle or other suitable device, and then further ground into a more fine powder with a ball mill, rod mill or the like (step 1.2). In a ball milling process, for example, the coarse PbTe powder may be placed in a sealable container along with a solvent, such as n-Heptane, and zirconia balls of predetermined diameter (e.g., approximately 1 cm). The container is then rotated using an automatic turning machine or other device to further grind the PbTe powder.

In an embodiment of the invention, the milling process is performed for a predetermined duration of time ranging from about one hour to several days, with longer milling times producing a smaller PbTe grain size. In a particular implementation of the invention, the PbTe powder was ball milled for 70 hours in n-Heptane. Alternatively, the PbTe powder can be ball milled in an inert atmosphere, such as argon. A typical particle size of the PbTe powder after the milling process is generally on the order of 5 to 150 nm, but is not necessarily limited thereto.

For some samples, additional material, including without limitation PbEuTe and PbSnTe alloys, fullerene (C60) powder and silica powder, may be added to the container to create composite PbTe materials tailored to provide the desired thermoelectric properties. The addition of these materials, while influential to the overall thermoelectric properties of the material, is not essential to the enhancement of the Seebeck coefficient in the material. Ball milling is an efficient way of grinding as well as alloying a variety of thermoelectric materials. Mechanical alloying as a material synthesis technology exhibits several advantages compared to other established technologies. For example, compositions that are difficult to prepare by melt metallurgy or other ways, are attainable with defined constitution and reproducible properties.

After the reducing process, the relatively fine PbTe-based powder is passed through a sieve or other filtering device (step 1.3). Particles having a grain size below several microns are separated from those particles having a grain size greater than several microns-the smaller particles being more desirable. For all thermoelectric materials prepared using the method of the present invention, the desired grain size (d) of the nanogranular thermoelectric material is selected based on the mean free path of electrons due to phonon scattering in the corresponding bulk thermoelectric material. Particularly, the desired grain size (d) of a nanogranular thermoelectric material is represented by the following relationship:

mfp/2<d<5mfp

where mfp is the phonon-limited mean free path of the electrons (or holes) in the corresponding bulk thermoelectric material. It has been determined that when the grain size (d) corresponds nearly to, or is even slightly smaller than, the mean free path due to phonon scattering, the energy dependence for the scattering rate of the carrier changes-this change enhancing the Seebeck coefficient.

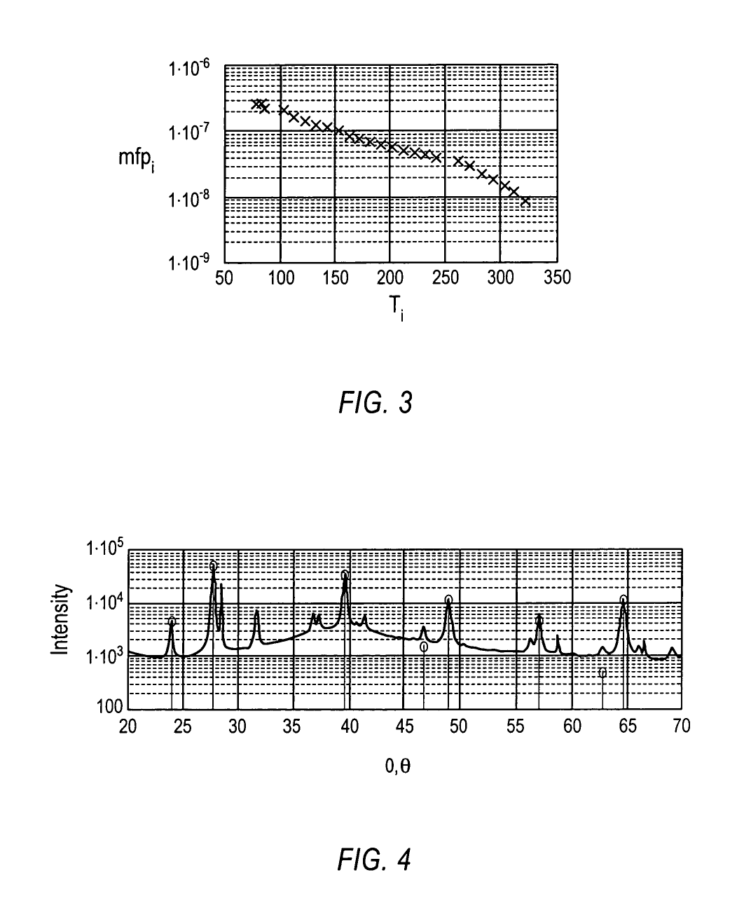

As illustrated in FIG. 3, the phonon-limited mean free path of a particular bulk PbTe-based thermoelectric material prepared in accordance with the method of the present invention was determined to be about 20 nm at approximately room temperature. Accordingly, the desired grain size for the material is between 10 nm and 100 nm, as defined by the relationship noted above. In a particular implementation of the invention, the relatively fine PbTe-based powder was milled until the particles ranged in size between approximately 10 nm and 100 nm.

The retained PbTe-based powder, having the desired grain size, is then dried and isostatically or uniaxially pressed at a predetermined pressure, such as for example, a pressure of approximately 200 MPa (approximately 30,000 psi) at room temperature (step 1.4) for the isostatic method. In another example, as shown in the embodiment of FIG. 1, the retained PbTe-based powder may be placed in a uniaxial press having a die cavity of predetermined dimension and a plunger for applying the predetermined pressure. The pressure applied by the plunger presses the PbTe-based powder into a pellet or other structure having a shape defined by the die cavity and plunger.

The resulting pellet may then be placed in a quartz ampoule, for example, and sintered at a temperature of about 350° C. to 450° C. for approximately 15 minutes to 200 hours, typically around 160-170 hours at 350° C., in order to consolidate the material and grow crystallites of appropriate size (step 1.5). This sintering may take place in a reducing atmosphere, such as hydrogen gas, to reduce surface oxides on the pressed material. In an embodiment, several PbTe-based pellets were placed in a furnace at about 347° C. for around 170 hours. The resulting PbTe-based nanogranular thermoelectric material exhibited an average grain size of about 30 nm, as measured by Scherer analysis of X-ray diffraction line width. Particularly, as shown in the representative XRD spectrum of FIG. 4, the broad PbTe peaks are identified with markers. The peak at around 28 degrees is given by a reference KCI crystal, and measures the instrumental broadening. The PbTe peaks' broadening corresponds to a crystallite size of about 30 nm.

In an embodiment of the invention, the sintered pellets prepared in accordance with the above-described method were sectioned for Hall measurements to determine the carrier concentration and also for Seebeck measurements. FIG. 2 illustrates the Seebeck coefficient as a function of electron (or hole) density at about room temperature (e.g., about 300 K) for various PbTe-based thermoelectric material samples prepared according to method of the present invention. A substantial increase in the Seebeck coefficient may be observed on several samples. More particularly, the bold uninterrupted line represents the theoretical Seebeck coefficient for bulk PbTe, and the open squares are data points obtained on bulk PbTe ingots prepared according to the method of the present invention. The shaded circles represent QDSL structures according to the prior art, which were prepared using molecular beam epitaxy (MBE). The shaded squares represent PbTe-based thermoelectric nanogranular material samples prepared according to the method of the present invention having grain sizes between approximately 10 nm and 100 nm, and more particularly about 30 nm. As illustrated in FIG. 2, the PbTe-based thermoelectric nanogranular material samples prepared using the method of the present invention exhibit a Seebeck coefficient similar to the QDSL thermoelectric materials prepared using molecular beam epitaxy.

For comparison, FIG. 2 also illustrates samples prepared using the method of the present invention, but sintered for a longer period of time (see, e.g., those samples that were sintered for an additional 179 hours beyond the recommended time), or at higher temperatures (e.g., 650° C.). As shown in FIG. 2, those samples that were sintered at a higher temperature exhibited a Seebeck coefficient closer to that exhibited by the “bulk” material, while the samples sintered for a longer period of time did not necessarily exhibit degradation in the Seebeck coefficient.

Among other benefits, PbTe-based nanogranular materials prepared using the method of the present invention exhibit enhanced Seebeck coefficients, particularly when the grain size is in the range of about 10 nm to 100 nm, and a decrease in thermal conductivity. As noted above, the method of the present invention is not limited to preparing PbTe-based thermoelectric nanogranular materials and may be used to prepare other thermoelectric nanogranular materials with a grain size prescribed by the relationship provided above.

The present invention has been particularly shown and described with reference to the foregoing embodiments, which are merely illustrative of the best modes for carrying out the invention. It should be understood by those skilled in the art that various alternatives to the embodiments of the invention described herein may be employed in practicing the invention without departing from the spirit and scope of the invention as defined in the following claims. It is intended that the following claims define the scope of the invention and that the method and apparatus within the scope of these claims and their equivalents be covered thereby. This description of the invention should be understood to include all novel and non-obvious combinations of elements described herein, and claims may be presented in this or a later application to any novel and non-obvious combination of these elements. Moreover, the foregoing embodiments are illustrative, and no single feature or element is essential to all possible combinations that may be claimed in this or a later application.

What is claimed is:

1. A thermoelectric nanogranular material with an enhanced Seebeck coefficient, comprising:
a processed thermoelectric nanogranular material including particles having a grain size d;
wherein d is characterized by the relationship mfp/2<d<5mfp; and
wherein mfp is the phonon-limited mean free path of an equivalent bulk thermoelectric material prior to processing a bulk thermoelectric material into the processed thermoelectric nanogranular material having a grain size d.

2. The thermoelectric nanogranular material of claim 1, wherein the thermoelectric nanogranular material includes PbTe.

3. The thermoelectric nanogranular material of claim 2, wherein the grain size d of the PbTe thermoelectric nanogranular material is between approximately 10 nm and 100 nm.

4. The thermoelectric nanogranular material of claim 1, wherein the thermoelectric nanogranular material includes one of PbSe, PbS, SnTe, SnSe and their solid solutions.

5. The thermoelectric nanogranular material of claim 1, wherein the thermoelectric nanogranular material includes one of Bi₂Te₃, Bi₂Se₃, Sb₂Te₃, Sb₂Se₃ and their solid solutions.

6. The thermoelectric nanogranular material of claim 1, wherein the thermoelectric nanogranular material includes BiSb.

7. The thermoelectric nanogranular material of claim 1, wherein the grain size d is between approximately 10 nm and 100 nm.

8. A method of making a thermoelectric nanogranular material, comprising the steps of:
preparing a bulk thermoelectric material;
reducing the bulk thermoelectric material into a powder;
processing the powder to retain only those particles having a grain size d, wherein:
d is characterized by the relationship mfp/2<d<5mfp; and
mfp is the phonon-limited mean free path of the bulk thermoelectric material;
pressing the retained particles at a predetermined pressure; and
sintering the pressed particles at a predetermined temperature for a predetermined period of time in a predetermined atmosphere.

9. The method of claim 8, wherein the step of preparing a bulk thermoelectric material includes preparing a PbTe-based thermoelectric material.

10. The method of claim 9, wherein the processing step includes filtering the powder to retain only those particles having a grain size d between approximately 10 nm and 100 nm.

11. The method of claim 8, wherein the step of preparing a bulk thermoelectric material includes preparing a PbSe, PbS, SnTe or SnSe material.

12. The method of claim 8, wherein the step of preparing a bulk thermoelectric material includes preparing a Bi₂Te₃, Bi₂Se₃, Sb₂Te₃ or Sb₃Se₃ material.

13. The method of claim 8, wherein the step of preparing a bulk thermoelectric material includes preparing a BiSb material.

14. The method of claim 8, wherein the step of preparing a bulk thermoelectric material includes alloying the bulk material to endow the material with the desired electron or hole density.

15. The method of claim 8, wherein the reducing step includes ball-milling the bulk thermoelectric material in n-Heptane.

16. The method of claim 8, wherein the reducing step includes ball-milling the bulk thermoelectric material in an inert atmosphere.

17. The method of claim 8, wherein the reducing step includes alloying the bulk thermoelectric material to influence the thermoelectric properties.

18. The method of claim 8, wherein the pressing step includes isostatically or uniaxially pressing the retained particles.

19. The method of claim 8, wherein the sintering step includes sintering the pressed particles at approximately 350° C. to 450° C. for between about 15 minutes and 200 hours.

20. The method of claim 19, wherein the sintering step includes sintering the pressed particles at approximately 350° C. for between 150 and 200 hours.

21. The method of claim 19, wherein the sintering step includes sintering the pressed particles at approximately 450° C. for about 15 minutes.

22. The method of claim 19, wherein the sintering step includes sintering the pressed particles for approximately 160-170 hours.

23. The method of claim 8, wherein the sintering step includes sintering the pressed particles in a reducing atmosphere.

24. The method of claim 8, wherein the sintering step includes sintering the pressed particles in hydrogen gas.

25. The method of claim 8, wherein the step of reducing the bulk thermoelectric material includes adding fullerene (C60) powder to the bulk thermoelectric material.
